(19) United States
(12) Patent Application Publication
(10) Pub. No.: US 2024/0310869 A1
(43) Pub. Date: Sep. 19, 2024

(54) Memory system, memory access interface device and operation method thereof

(71) Applicant: REALTEK SEMICONDUCTOR CORP., Hsinchu (TW)

(72) Inventors: FU-CHIN TSAI, Hsinchu (TW); CHUN-CHI YU, Hsinchu (TW); GER-CHIH CHOU, Hsinchu (TW); CHIH-WEI CHANG, Hsinchu (TW)

(21) Appl. No.: 18/122,908

(22) Filed: Mar. 17, 2023

(51) Int. Cl. G06F 1/08

(52) U.S. Cl. CPC G06F 1/08

(57) ABSTRACT

The present disclosure discloses a memory access interface device. A signal training circuit is configured for performing following steps. A transmitting circuit transmits a training data signal and a training data strobe signal as an output data signal and an output data strobe signal to a memory device according to timing reference signals. A read data signal from the memory device is received. The training data signal and the read data signal are compared to generate a comparison result indicating whether the read data signal matches the training data signal. The comparison result is stored. The clock generation circuit is controlled to modify a phase of one of the timing reference signals, further modifying the timing of one of the training data signal and the training data strobe signal, to be one of under-test phases to execute a new loop of a training process.

### BACKGROUND OF THE INVENTION

### 1. Field of the Invention

The present disclosure relates to a memory system, a memory access interface device and a memory access interface device operation method thereof.

### 2. Description of Related Art

When memory devices, e.g., low power double data rate (LPDDR) synchronous dynamic random access memory devices, are mass-produced, corresponding parameters of each of the memory devices may vary due to the different conditions the devices meet during processing, packaging and the printed circuit boards that the devices are disposed.

The timing parameters related to the transmission of data of the memory devices affect the accessing of the data. If the timing parameters are set to be the same among these memory devices, the yield may become low. As a result, a training process is required to obtain the preferable timing parameters related to the transmission of data such that the accuracy of the accessing of the memory devices can be maintained.

### SUMMARY OF THE INVENTION

In consideration of the problem of the prior art, an object of the present disclosure is to provide a memory system, a memory access interface device and a memory access interface device operation method thereof.

The present disclosure discloses a memory access interface device that includes a clock generation circuit, a transmitting circuit, a receiving circuit and a signal training circuit. The signal training circuit is configured for performing the steps outlined below. For one of a plurality of loops of a training process in a training mode, a training data signal and a training data strobe signal are generated such that the transmitting circuit selects the training data signal and the training data strobe signal to be transmitted as an output data signal and an output data strobe signal to a memory device according to a plurality of timing reference signals generated according to the clock generation circuit each having a phase. A read data signal is received from the receiving circuit, wherein the receiving circuit receives a returned data signal and a returned data strobe signal generated by the memory device to generate the read data signal accordingly. A content of the training data signal and the read data signal are compared to generate a comparison result indicating whether the read data signal matches the content of the training data signal. The comparison result is stored. The clock generation circuit is controlled to modify a phase of at least one of the timing reference signals, further modifying the timing of one of the training data signal and the training data strobe signal, to be one of a plurality of under-test phases to execute a new loop of the loops of the training process.

The present disclosure also discloses a memory system that includes a memory access controller, a memory device and a memory access interface device. The memory access interface device includes a clock generation circuit, a transmitting circuit, a receiving circuit and a signal training circuit. The signal training circuit is configured for performing the steps outlined below. For one of a plurality of loops of a training process in a training mode, a training data signal and a training data strobe signal are generated such that the transmitting circuit selects the training data signal and the training data strobe signal to be transmitted as an output data signal and an output data strobe signal to the memory device according to a plurality of timing reference signals generated according to the clock generation circuit each having a phase. A read data signal is received from the receiving circuit, wherein the receiving circuit receives a returned data signal and a returned data strobe signal generated by the memory device to generate the read data signal accordingly. A content of the training data signal and the read data signal are compared to generate a comparison result indicating whether the read data signal matches the content of the training data signal. The comparison result is stored. The clock generation circuit is controlled to modify a phase of at least one of the timing reference signals, further modifying the timing of one of the training data signal and the training data strobe signal, to be one of a plurality of under-test phases to execute a new loop of the loops of the training process.

The present disclosure also discloses a memory access interface device operation method that includes the steps outlined below. For one of a plurality of loops of a training process in a training mode, a training data signal and a training data strobe signal are generated by a signal training circuit of a memory access interface device such that a transmitting circuit of the memory access interface device selects the training data signal and the training data strobe signal to be transmitted as an output data signal and an output data strobe signal to a memory device according to a plurality of timing reference signals generated according to the clock generation circuit each having a phase. A read data signal is received from a receiving circuit of the memory access interface device by the signal training circuit, wherein the receiving circuit receives a returned data signal and a returned data strobe signal generated by the memory device to generate the read data signal accordingly. A content of the training data signal and the read data signal are compared by the signal training circuit to generate a comparison result indicating whether the read data signal matches the content of the training data signal. The comparison result is stored by the signal training circuit. The clock generation circuit is controlled by the signal training circuit to modify the phase of one of the timing reference signals, further modifying the timing of one of the training data signal and the training data strobe signal, to be one of a plurality of under-test phases to execute a new loop of the loops of the training process.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a block diagram of a memory system according to an embodiment of the present invention.

FIG. 2 illustrates a detailed block diagram of the memory access interface device in FIG. 1 according to an embodiment of the present invention.

FIG. 3 illustrates a detailed block diagram of the signal training circuit in FIG. 2 according to an embodiment of the present invention.

FIG. 4 illustrates a diagram of various signals related to the operation of the memory access interface device in the training mode according to another embodiment of the present invention.

FIG. 5 illustrates a diagram of various signals related to the operation of the memory access interface device in the training mode according to another embodiment of the present invention.

FIG. 6 illustrates a flow chart of a memory access interface device operation method according to an embodiment of the present invention.

FIG. 7 illustrates a more detailed flow chart of a memory access interface device operation method according to an embodiment of the present invention.

### DETAILED DESCRIPTION OF THE PREFERRED EMBODIMENTS

An aspect of the present invention is to provide a memory system, a memory access interface device and a memory access interface device operation method thereof to perform training on the timing reference signals by modifying the phases thereof and determine whether the phases are valid according to the comparison result between the content of the transmitted training data signal and the read data signals returned by the memory device. The preferable phases of the timing reference signals can be further obtained according to the valid phases.

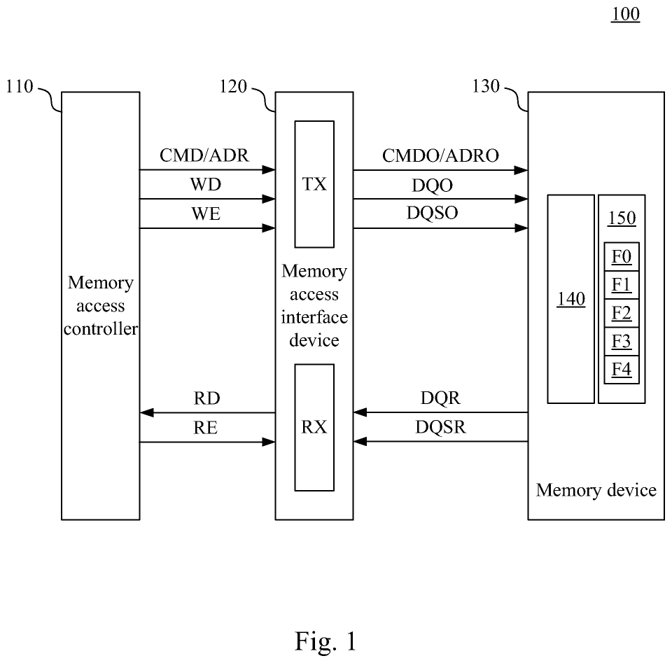

Reference is now made to FIG. 1. FIG. 1 illustrates a block diagram of a memory system 100 according to an embodiment of the present invention. The memory system 100 includes a memory access controller 110, a memory access interface device 120 and a memory device 130.

The memory system 100 can be electrically coupled to other modules through such as, but not limited to a system bus (not illustrated). For example, the memory system 100 can be electrically coupled to a processor (not illustrated) through a system bus such that the processor can access the memory system 100.

In an embodiment, the memory access interface device 120 can be such as, but not limited to a physical layer circuit.

The memory device 130 is preferably a LPDDR memory device, e.g., a LPDDR4 memory. In an embodiment, the memory device 130 includes a memory storage circuit 140 and a first-in-first-out (FIFO) circuit 150.

External access signals, e.g. the access signals from the processor, can be received by the memory access controller 110 first and can be transmitted to the memory access interface device 120. Further, the access signals can be either transmitted from the memory access interface device 120 to the memory device 130 or used as a reference within the memory access interface device 120 to access the memory device 130.

The memory access interface device 120 substantially includes a transmitting circuit TX and a receiving circuit RX. As a result, different access signals may be transmitted depending on the operation of the transmitting circuit TX and the receiving circuit RX.

For the transmitting circuit TX, the memory access controller 110 can transmit the access signals including such as, but not limited to a command and address signal CMD/ADR to the memory access interface device 120. The memory access controller 110 can also transmit a write data signal WD and a write enable signal WE to the memory access interface device 120.

The memory access interface device 120 applies latency on the access signals to generate output access signals. More specifically, the memory access interface device 120 applies latency on the command and address signal CMD/ADR to adjust the timing thereof to generate an output command and address signal CMDO/ADRO to the memory device 130. On the other hand, the memory access interface device 120 may also apply latency on the write data signal WD and the write enable signal WDE to adjust the timing thereof to generate an output data signal DQO and an output data strobe signal DQSO to the memory device 130.

For the receiving circuit RX, the memory access interface device 120 can receive a returned data signal DQR and a returned data strobe signal DQSR from the memory device 130 through a data transmission path and sample the returned data signal DQR according to the returned data strobe signal DQSR to generate a read data signal RD to the memory access controller 110. In an embodiment, the receiving circuit RX receives a read enable signal RE to perform the operation described above.

As a result, the internal data of the memory device 130 can thus be accessed according to the correct timing of the signals described above.

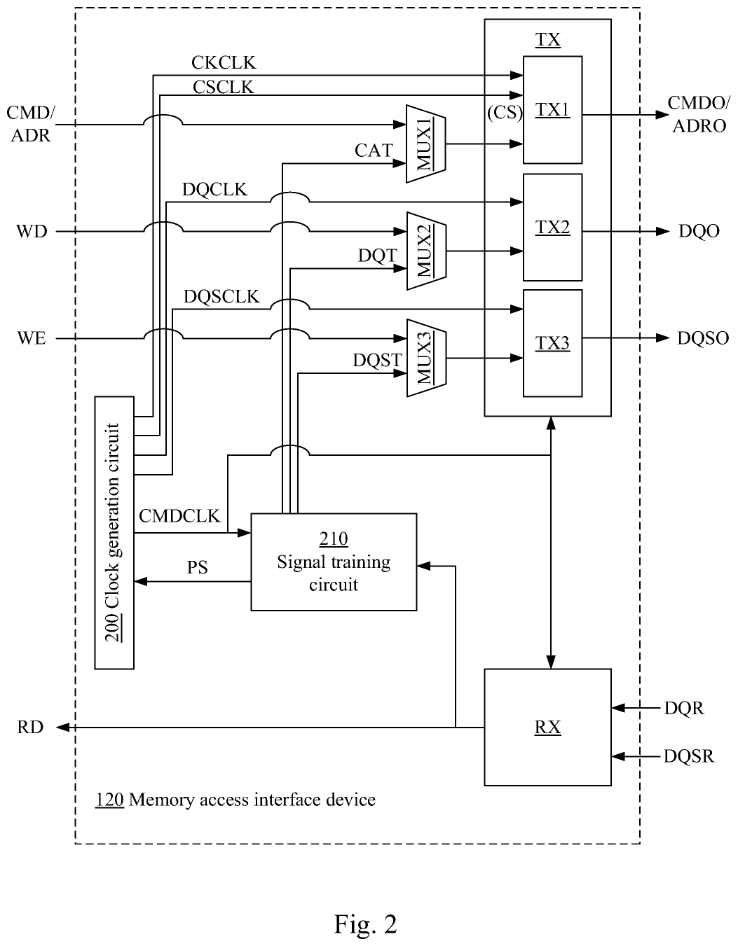

Reference is now made to FIG. 2 at the same time. FIG. 2 illustrates a detailed block diagram of the memory access interface device 120 in FIG. 1 according to an embodiment of the present invention.

Besides the transmitting circuit TX and the receiving circuit RX, the memory access interface device 120 further includes a clock generation circuit 200 and a signal training circuit 210.

In an embodiment, the memory access interface device 120 is set to operate in either a training mode or an operation mode by the memory access controller 110. More specifically, in an embodiment, the processor that the memory system 100 is electrically coupled to may operate a software (not illustrated) to issue a command such that the memory access controller 110 receives the command and control the memory access interface device 120 to operate in either the training mode or the operation mode.

In the following paragraphs, the operation of the memory access interface device 120 in the training mode is described first.

The clock generation circuit 200 is configured for generating a plurality of clock signals. In an embodiment, the clock signals include a clock signal CKCLK, a chip select clock signal CSCLK, a data clock signal DQCLK and a data strobe clock signal DQSCLK.

In an embodiment, the transmitting circuit TX operates according to a command clock signal CMDCLK generated by the clock generation circuit 200. The transmitting circuit TX is configured for transmitting the output command and address signal CMDO/ADRO, the output data signal DQO and the output data strobe signal DQSO to the memory device 130 according to a plurality of timing reference signals each having a phase generated according to the clock generation circuit 200.

More specifically, the transmitting circuit TX transmits the output command and address signal CMDO/ADRO that indicating write operation according to the clock signal CKCLK and the chip select signal CS. Further, the transmitting circuit TX transmits the output data signal DQO according to the data clock signal DQCLK and transmits the output data strobe signal DQSO according to the data strobe clock signal DQSCLK to the memory device 130 to perform write operation thereon according to the output command and address signal CMDO/ADRO.

In an embodiment, the clock signal CKCLK, the data clock signal DQCLK and the data strobe clock signal DQSCLK are provided by the clock generation circuit 200 and are directly used as timing reference signals. The chip select signal CS is generated in the transmitting circuit TX, e.g., by using a D flip-flop circuit therein, according to the chip select clock signal CSCLK provided by the clock generation circuit 200, in which the chip select clock signal CSCLK includes a plurality of consecutive clock pulses and the chip select signal CS includes a single signal pulse every predetermined time period.

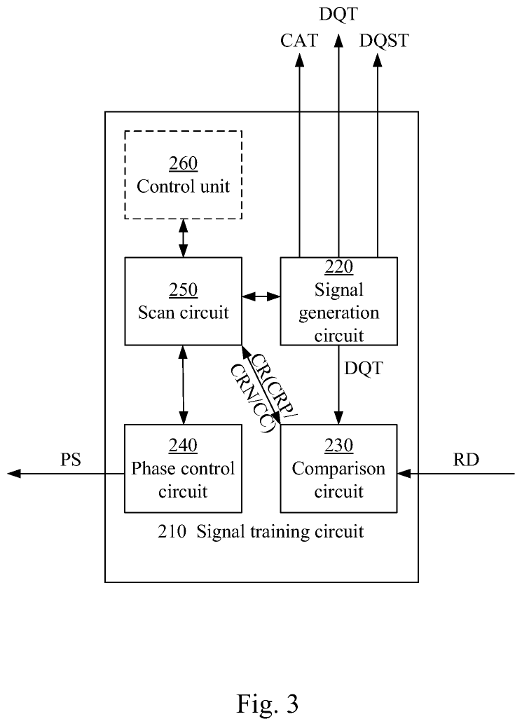

Reference is now made to FIG. 3 at the same time. FIG. 3 illustrates a detailed block diagram of the signal training circuit 210 in FIG. 2 according to an embodiment of the present invention.

In an embodiment, the signal training circuit 210 operates according to a command clock signal CMDCLK generated by the clock generation circuit 200 illustrated in FIG. 2. The signal training circuit 210 includes a signal generation circuit 220, a comparison circuit 230, a phase control circuit 240, a scan circuit 250 and a control unit 260.

The signal training circuit 210 executes a plurality of loops of a training process in the training mode. The training process executed by signal training circuit 210 is described in accompany with the description of the configuration and operation of the components included therein.

The signal generation circuit 220 is configured for generating a training command and address signal CAT such that the transmitting circuit TX selects the training command and address signal CAT to be transmitted as the output command and address signal CMDO/ADRO, in which the output command and address signal CMDO/ADRO is transmitted to the memory device 130.

The signal generation circuit 220 is also configured for generating a training data signal DQT and a training data strobe signal DQST, in which the data clock signal DQCLK corresponds to the training data signal DQT and the data strobe clock signal DQSCLK corresponds to the training data strobe signal DQST. The transmitting circuit TX selects the training data signal DQT and the training data strobe signal DQST to be transmitted as the output data signal DQO and the output data strobe signal DQSO to the memory device 130.

In an embodiment, the memory access interface device 120 further includes multiplexers MUX1-MUX3 coupled to the transmitting circuit TX, and the transmitting circuit TX includes transmitting units TX1-TX3.

The multiplexer MUX1 is a command and address multiplexer such that the transmitting unit TX1 of the transmitting circuit TX selects the training command and address signal CAT to be transmitted as the output command and address signal CMDO/ADRO in the training mode.

The multiplexer MUX2 is a data multiplexer such that the transmitting unit TX2 of the transmitting circuit TX selects the training data signal DQT to be transmitted as the output data signal DQO in the training mode. The multiplexer MUX3 is a data strobe multiplexer such that the transmitting unit TX3 of the transmitting circuit TX selects the training data strobe signal DQST as the output data strobe signal DQSO in the training mode.

In an embodiment, when the transmitting unit TX1 selects the training command and address signal CAT that indicates write operation as the output command and address signal CMDO/ADRO in the training mode, the first-in-first-out circuit 150 having a predetermined depth of the memory device 130 in FIG. 1 is accessed accordingly, in which the output data signal DQO and the output data strobe signal DQSO are written to the first-in-first-out circuit 150.

In FIG. 1, the depth of the first-in-first-out circuit 150 is 5. As a result, the first-in-first-out circuit 150 includes 5 first-in-first-out units F0-F4 to receive the output data signal DQO and the output data strobe signal DQSO. However, the depth of the first-in-first-out circuit 150 illustrated in FIG. 1 is merely an example and can be different numbers according to practical requirements.

Further, when the transmitting unit TX1 selects another training command and address signal CAT that indicates read operation as the output command and address signal CMDO/ADRO in the training mode, the first-in-first-out circuit 150 is accessed accordingly, in which the returned data signal DQR and the returned data strobe signal DQSR are generated by the first-in-first-out circuit 150.

In an embodiment, the receiving circuit RX operates according to the command clock signal CMDCLK generated by the clock generation circuit 200. The receiving circuit RX receives the returned data signal DQR and the returned data strobe signal DQSR generated by the memory device 130 to generate the read data signal RD accordingly.

The comparison circuit 230 receive the read data signal RD from the receiving circuit RX and is configured for comparing a content of the training data signal DQT and the read data signal RD from the receiving circuit RX which is generated by the memory device 130 to generate a comparison result CR indicating whether the read data signal RD matches the training data signal DQT.

In an embodiment, since the memory device 130 is preferably a LPDDR memory device, the comparison result CR includes a positive edge result CRP and a negative edge result CRN respectively corresponding to the data generated according to a positive sampling edge and a negative sampling edge of the returned data strobe signal DQSR. The comparison result CR may further selectively includes a composite result CC generated by performing OR logic operation on the positive edge result CRP and the negative edge result CRN.

The phase control circuit 240 is configured for generating a phase control signal PS to control the clock generation circuit 200 to modify the phase of one of the timing reference signals, e.g., one of the data clock signal DQCLK and the data strobe clock signal DQSCLK. In an embodiment, the phases of the clock signal CKCLK and the chip select signal CS can be trained in an additional training process, which is not described in detail herein, in advance to guarantee the accuracy thereof.

The scan circuit 250 is configured for controlling the signal generation circuit 220 and the phase control circuit 240 to execute the loops of the training process. In the training process, a first one of the data clock signal DQCLK and the data strobe clock signal DQSCLK is selected as a selected clock signal and a second one of the data clock signal DQCLK and the data strobe clock signal DQSCLK is a non-selected clock signal. When a loop of the training process is finished, the phase of the selected clock signal is modified to be one of a plurality of under-test phases to execute a new loop of the loops of the training process until all the under-test phases are trained.

The scan circuit 250 is further configured for storing the comparison result CR in each of the loops of the training process.

The control unit 260 is configured for providing test data for generating the training command and address signal CAT, the training data signal DQT and the training data strobe signal DQST such that the scan circuit 250 controls the signal generation circuit 220 to generate the training command and address signal CAT, the training data signal DQT and the training data strobe signal DQST accordingly. Further, the control unit 260 is configured for accessing the comparison result CR stored by the scan circuit 250 to determine a preferable clock phase of the selected clock signal (i.e., one of the data clock signal DQCLK and the data strobe clock signal DQSCLK).

In an embodiment, the control unit 260 can be implemented by using hardware circuit disposed in the signal training circuit 210. In another embodiment, the control unit 260 can be implemented by using software operated by the processor coupled to the memory system 100. Under the condition that the control unit 260 is implemented by using software, the control unit 260 may provide the test data to a register in the signal training circuit 210 for the scan circuit 250 to access, the scan circuit 250 may store the comparison result CR in another register for the control unit 260 to access.

The loops of the training process performed by the signal training circuit 210 are described in detail below.

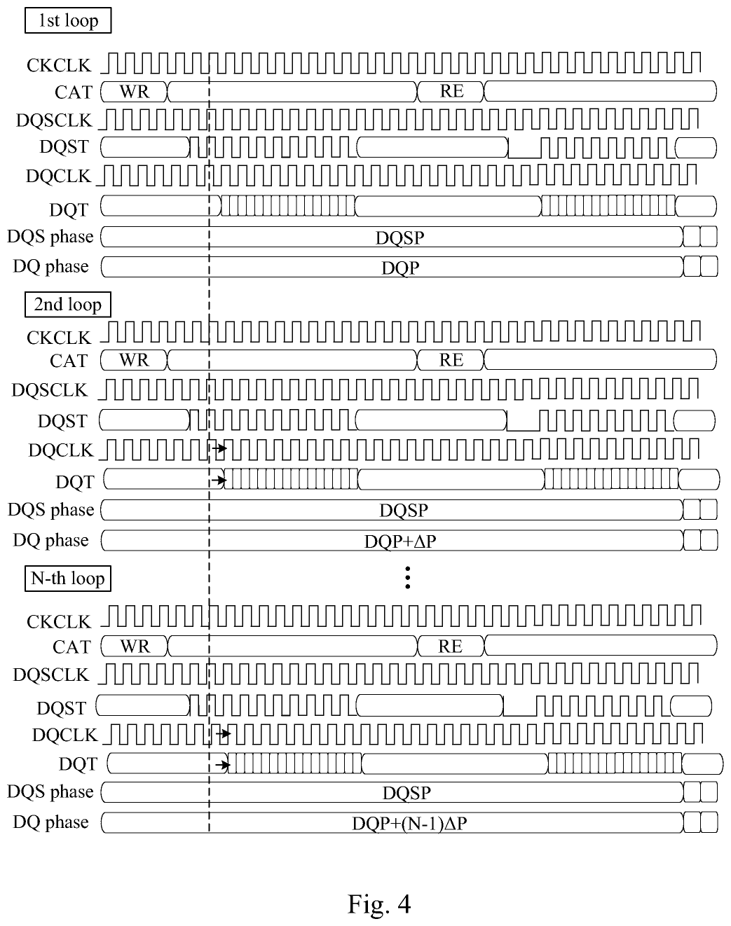

FIG. 4 illustrates a diagram of various signals related to the operation of the memory access interface device 120 in the training mode according to an embodiment of the present invention.

In FIG. 4, the phase of the training command and address signal CAT corresponds to the clock signal CKCLK, in which the training command and address signal CAT includes a write operation command WR and a read operation command RE.

The phase of the training data signal DQT corresponds to the data clock signal DQCLK since the training data signal DQT is transmitted according to the data clock signal DQCLK. The phase of the training data strobe signal DQST corresponds to the data strobe clock signal DQSCLK since the training data strobe signal DQST is transmitted according to the data strobe clock signal DQSCLK.

In the present embodiment, the data clock signal DQCLK is selected as the selected clock signal and the data strobe clock signal DQSCLK is the non-selected clock signal. The clock generation circuit 200 keeps the phase of the non-selected clock signal, i.e., the data strobe clock signal DQSCLK, to be a first preferable clock phase.

As illustrated in FIG. 4, N loops of the training process are exemplarily illustrated. The phase of the data clock signal DQCLK is modified in each loop of the training process. As a result, each of the loops of the training process corresponds to one of N under-test phases of the data clock signal DQCLK, N being a positive integer.

In the present embodiment, in the first loop of the training process, the phase of the data clock signal DQCLK has a predetermined phase DQP and the phase of the data strobe clock signal DQSCLK has a predetermined phase DQSP. For the second loop of the first stage process, the phase of the data clock signal DQCLK is modified to be a next under-test phase, which is a sum of the predetermined phase DQP and a unit phase ΔP. The arrows depicted at the data clock signal DQCLK in the 2nd loop and the N-th loop in FIG. 4 indicates the direction of the modification of the phase of the data clock signal DQCLK and the training data signal DQT corresponding thereto. The phase of the data strobe clock signal DQSCLK is kept to be the predetermined phase DQSP.

As a result, each of the other loops of the training process can be performed subsequently until the N-th loop of the first stage process is performed. In the N-th loop of the training process, the phase of the data clock signal DQCLK is modified to be a sum of the predetermined phase DQP and N−1 unit phases AP, which is expressed as DQP+(N−1)ΔP. The phase of the data strobe clock signal DQSCLK is kept to be the predetermined phase DQSP.

The comparison circuit 230 in FIG. 3 can therefore compare the content of the training data signal DQT and the read data signal RD and generate the comparison result CR in each of the loops.

It is appreciated that the number of the under-test phases, which corresponds to the number of the loops of the training process to be performed, is determined according to a required accuracy within a clock period of the data clock signal DQCLK.

For example, the time period of the data clock signal DQCLK can be divided into 8 phases each corresponding to the unit phase ΔP described above such that 8 loops of the training process are performed. When a higher accuracy is required, the time period of the data clock signal DQCLK can be divided into 16 phases each corresponding to the unit phase ΔP described above such that 16 loops of the training process are performed.

Based on the comparison result CR from each of the loops of the training process stored by the scan circuit 250 in FIG. 3, one of the under-test phases of the data clock signal DQCLK is determined to be valid when the corresponding comparison result CR indicates that the read data signal RD matches the content of the training data signal DQT. A second preferable clock phase of the selected clock signal, i.e., the data clock signal DQCLK, can be obtained according to the valid under-test phases. For example, a central phase of the valid phases of the data clock signal DQCLK can be selected as the second preferable clock phase of the data clock signal DQCLK.

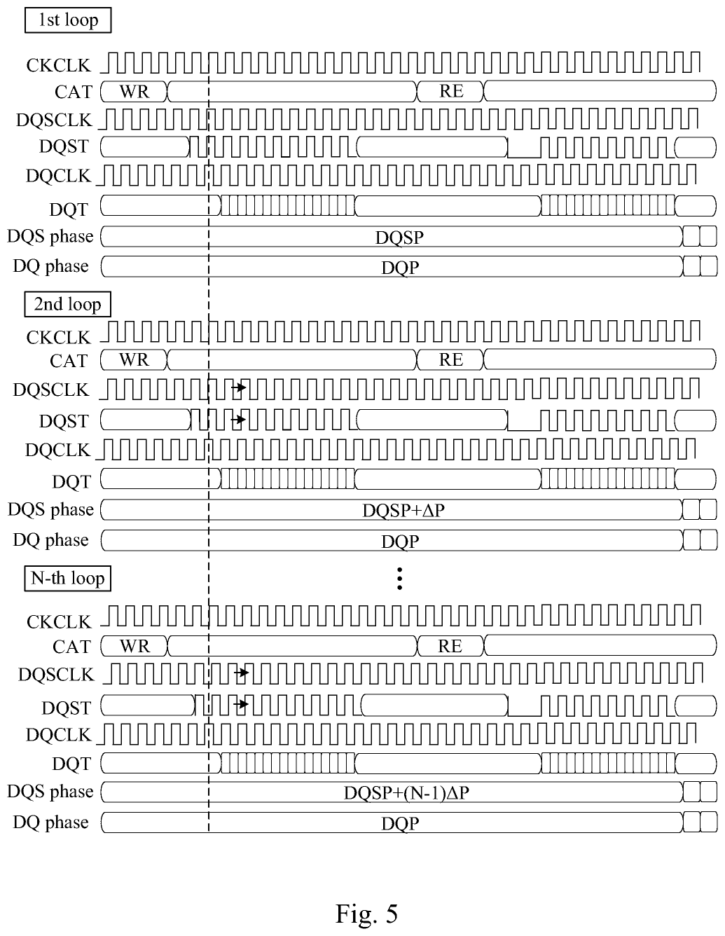

FIG. 5 illustrates a diagram of various signals related to the operation of the memory access interface device 120 in the training mode according to another embodiment of the present invention.

In FIG. 5, the phase of the training command and address signal CAT corresponds to the clock signal CKCLK, in which the training command and address signal CAT includes a write operation command WR and a read operation command RE.

The phase of the training data signal DQT corresponds to the data clock signal DQCLK since the training data signal DQT is transmitted according to the data clock signal DQCLK. The phase of the training data strobe signal DQST corresponds to the data strobe clock signal DQSCLK since the training data strobe signal DQST is transmitted according to the data strobe clock signal DQSCLK.

In the present embodiment, the data strobe clock signal DQSCLK is selected as the selected clock signal and the data clock signal DQCLK is the non-selected clock signal. The clock generation circuit 200 keeps the phase of the non-selected clock signal, i.e., the data clock signal DQCLK, to be a first preferable clock phase.

As illustrated in FIG. 5, N loops of the training process are exemplarily illustrated. The phase of the data strobe clock signal DQSCLK is modified in each loop of the training process. As a result, each of the loops of the training process corresponds to one of N under-test phases of the data strobe clock signal DQSCLK, N being a positive integer.

The training process illustrated in FIG. 5 is identical to the training process illustrated in FIG. 4, in which in the first loop of the training process, the phase of the data strobe clock signal DQSCLK has a predetermined phase DQSP such that the unit phase ΔP is incrementally added thereto and the comparison result CR is generated by the comparison circuit 230 in FIG. 3 in each of the loops. The arrows depicted at the data strobe clock signal DQSCLK in the 2nd loop and the N-th loop in FIG. 5 indicates the direction of the modification of the phase of the data strobe clock signal DQSCLK and the training data strobe signal DQST corresponding thereto. The phase of the data clock signal DQCLK has a predetermined phase DQP and is kept the same during the training process. As a result, the detail of the training process illustrated in FIG. 5 is not further described herein.

Based on the comparison result CR from each of the loops of the training process stored by the scan circuit 250 in FIG. 3, one of the under-test phases of the data strobe clock signal DQSCLK is determined to be valid when the corresponding comparison result CR indicates that the read data signal RD matches the content of the training data signal DQT. A second preferable clock phase of the selected clock signal, i.e., the data strobe clock signal DQSCLK, can be obtained according to the valid under-test phases. For example, a central phase of the valid phases of the data strobe clock signal DQSCLK can be selected as the preferable clock phase of the data strobe clock signal DQSCLK.

After the training process is performed, the memory access interface device 120 is set to operate in the operation mode by the memory access controller 110 in FIG. 1.

In the operation mode, the transmitting unit TX1 selects the command and address signal CMD/ADR transmitted by the memory access controller 110 to be transmitted as the output command and address signal CMDO/ADRO by using the multiplexer MUX1. The transmitting unit TX2 selects the write data signal WD transmitted by the memory access controller 110 to be transmitted as the output data signal DQO by using the multiplexer MUX2. The transmitting unit TX3 selects the write enable signal WE transmitted by the memory access controller 110 to be transmitted as the output data strobe signal DQSO by using the multiplexer MUX3.

The transmission of the output data signal DQO and the output data strobe signal DQSO is performed according to the first preferable phase of the selected clock signal and the second preferable phase of the non-selected clock signal. As a result, the memory device 130 can be accessed by the signals, e.g., the output data signal DQO and the output data strobe signal DQSO having the preferable timing.

The memory access interface device 120 in the present invention can perform training on the timing reference signals by modifying the phases thereof and determine whether the phases are valid according to the comparison result between the content of the transmitted training data signal and the read data signals returned by the memory device. The preferable phases of the timing reference signals can be further obtained according to the valid phases.

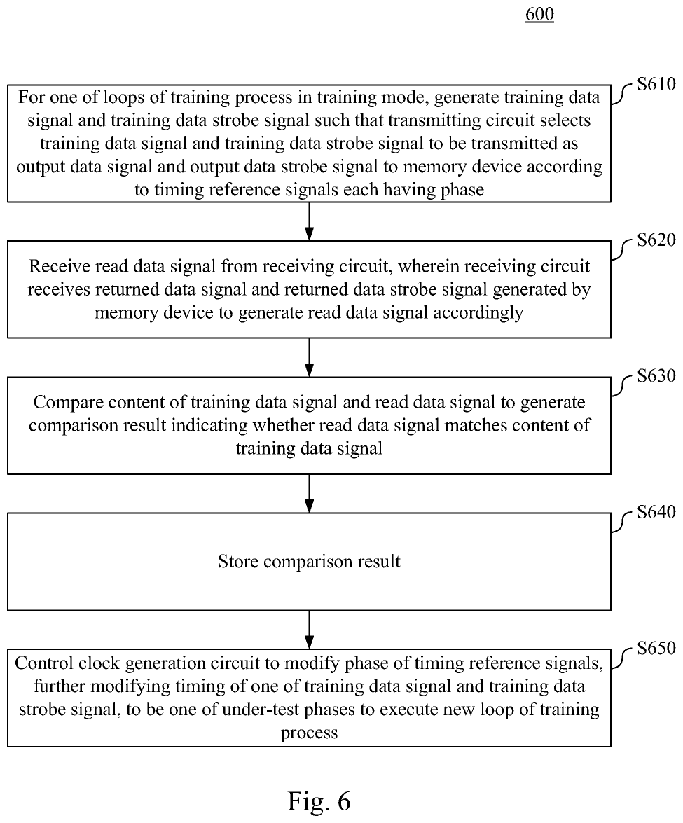

Reference is now made to FIG. 6. FIG. 6 illustrates a flow chart of a memory access interface device operation method 600 according to an embodiment of the present invention.

In addition to the apparatus described above, the present disclosure further provides the memory access interface device operation method 600 that can be used in such as, but not limited to, the memory access interface device 120 in FIG. 2. As illustrated in FIG. 6, an embodiment of the memory access interface device operation method 600 includes the following steps.

In step S610, for one of the plurality of loops of the training process in the training mode, the training data signal DQT and the training data strobe signal DQST are generated by the signal training circuit 210 of the memory access interface device 120 such that the transmitting circuit TX of the memory access interface device 120 selects the training data signal DQT and the training data strobe signal DQST to be transmitted as the output data signal DQO and the output data strobe signal DQSO to the memory device 130 according to the plurality of timing reference signals generated according to the clock generation circuit 200 each having the phase.

In step S620, the read data signal RD is received from the receiving circuit RX of the memory access interface device 120 by the signal training circuit 210, wherein the receiving circuit RX receives the returned data signal DQR and the returned data strobe signal DQSR generated by the memory device 130 to generate the read data signal RD accordingly.

In step S630, the content of the training data signal DQT and the read data signal RD are compared by the signal training circuit 210 to generate the comparison result CR indicating whether the read data signal RD matches the content of the training data signal DQT.

In step S640, the comparison result CR is stored by the signal training circuit 210.

In step S650, the clock generation circuit 200 is controlled by the signal training circuit 210 to modify the phase of one of the timing reference signals, further modifying the timing of one of the training data signal DQT and the training data strobe signal DQST, to be one of the plurality of under-test phases to execute the new loop of the loops of the training process until all the under-test phases are trained.

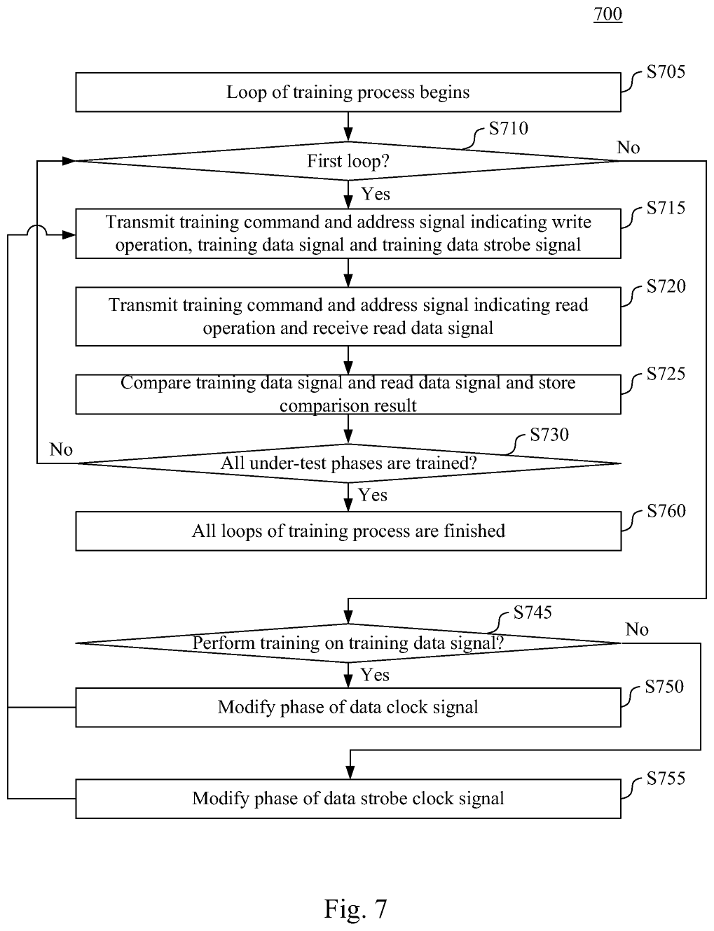

FIG. 7 illustrates a more detailed flow chart of a memory access interface device operation method according to an embodiment of the present invention. The memory access interface device operation method 700 can be used in the embodiment corresponding to FIG. 4 and FIG. 5.

In step S705, a loop of the training process begins.

In step S710, whether the loop is the first loop of the training process is determined.

In step S715, when the loop is the first loop of the training process, the training command and address signal CAT that indicates write operation is transmitted as the output command and address signal CMDO/ADRO, the training data signal DQT is transmitted as the output data signal DQO and the training data strobe signal DQST is transmitted as the output data strobe signal DQSO.

In step S720, the training command and address signal CAT that indicates read operation is transmitted as the output command and address signal CMDO/ADRO, and the read data signal RD is received.

In step S725, the training data signal DQT and the read data signal RD are compared and the comparison result CR is stored.

In step S730, whether all the under-test phases are trained or not is determined. When not all the under-test phases are trained, the flows goes back to step S710 to perform determination. A new loop of the training process begins.

In step S745, whether the previous loop performs training on the training data signal DQT is determined.

In step S750, when the previous loop performs training on the training data signal DQT, the phase of the data clock signal DQCLK is modified to perform subsequent steps of S715-S730.

In step S755, when the previous loop does not perform training on the training data signal DQT, the phase of the data strobe clock signal DQSCLK is modified to perform subsequent steps of S715-S730.

In step S760, when all the under-test phases are trained is determined in step S730, all the loops of the training process are finished.

It is appreciated that the embodiments described above are merely an example. In other embodiments, it should be appreciated that many modifications and changes may be made by those of ordinary skill in the art without departing, from the spirit of the invention.

In summary, the memory system, the memory access interface device and the memory access interface device operation method thereof perform training on the timing reference signals by modifying the phases thereof and determine whether the phases are valid according to the comparison result between the content of the transmitted training data signal and the read data signals returned by the memory device. The preferable phases of the timing reference signals can be further obtained according to the valid phases.

The aforementioned descriptions represent merely the preferred embodiments of the present disclosure, without any intention to limit the scope of the present disclosure thereto. Various equivalent changes, alterations, or modifications based on the claims of present disclosure are all consequently viewed as being embraced by the scope of the present disclosure.

What is claimed is:

1. A memory access interface device comprising:
a clock generation circuit;
a transmitting circuit;
a receiving circuit; and
a signal training circuit configured for:
for one of a plurality of loops of a training process in a training mode, generating a training data signal and a training data strobe signal such that the transmitting circuit selects the training data signal and the training data strobe signal to be transmitted as an output data signal and an output data strobe signal to a memory device according to a plurality of timing reference signals generated according to the clock generation circuit each having a phase;
receiving a read data signal from the receiving circuit, wherein the receiving circuit receives a returned data signal and a returned data strobe signal generated by the memory device to generate the read data signal accordingly;
comparing a content of the training data signal and the read data signal to generate a comparison result indicating whether the read data signal matches the content of the training data signal;
storing the comparison result; and
controlling the clock generation circuit to modify the phase of one of the timing reference signals, further modifying the timing of one of the training data signal and the training data strobe signal, to be one of a plurality of under-test phases to execute a new loop of the loops of the training process.

2. The memory access interface device of claim 1, wherein the timing reference signals comprise a data clock signal corresponding to the training data signal and a data strobe clock signal corresponding to the training data strobe signal, in which the data clock signal and the data strobe clock signal are provided by the clock generation circuit, the signal training circuit is further configured for:
selecting a first one of the data clock signal and the data strobe clock signal as a selected clock signal and a second one of the data clock signal and the data strobe clock signal as a non-selected clock signal;
controlling the clock generation circuit to keep the phase of the non-selected clock signal to be a first preferable clock phase;
controlling the clock generation circuit to modify the phase of the selected clock signal until all the under-test phases are trained;
determining one of the under-test phases of the selected clock signal is valid when the corresponding comparison result indicates that the read data signal matches the content of the training data signal; and
determining a second preferable clock phase of the selected clock signal according to the valid under-test phases.

3. The memory access interface device of claim 2, wherein the memory access interface device is set to operate in an operation mode such that the transmitting circuit selects a write data signal and a write enable signal to be transmitted as the output data signal and the output data strobe signal in the operation mode according to the non-selected clock signal having the first preferable phase and the selected clock signal having the second preferable phase.

4. The memory access interface device of claim 3, further comprising:
a data multiplexer coupled to the transmitting circuit such that the transmitting circuit selects the training data signal to be transmitted as the output data signal in the training mode and selects the write data signal as the output data signal in the operation mode by using the data multiplexer; and
a data strobe multiplexer coupled to the transmitting circuit such that the transmitting circuit selects the training data strobe signal to be transmitted as the output data strobe signal in the training mode and selects the write enable signal to be transmitted as the output data strobe signal in the operation mode by using the data strobe multiplexer.

5. The memory access interface device of claim 2, wherein the signal training circuit comprises:
a signal generation circuit configured for generating the training data signal and the training data strobe signal;
a comparison circuit configured for comparing the content of the training data signal and the read data signal to generate the comparison result;
a phase control circuit configured for generating a phase control signal to control the clock generation circuit to modify the phase of at least one of a plurality of clock signals to further modify the phase of at least one of the timing reference signals;
a scan circuit configured for controlling the signal generation circuit and the phase control circuit to execute the loops of the training process and storing the comparison result; and
a control unit configured for providing test data for generating the training data signal and the training data strobe signal and for accessing the comparison result to determine the first preferable clock phase of the non-selected clock signal and the second preferable clock phase of the selected clock signal.

6. The memory access interface device of claim 5, wherein the control unit is implemented by using software operated by a processor.

7. The memory access interface device of claim 5, wherein the comparison result comprises a positive edge result and a negative edge result, and further selectively comprises a composite result generated by performing OR logic operation on the positive edge result and the negative edge result.

8. The memory access interface device of claim 1, wherein the signal training circuit is further configured for generating a training command and address signal in the training mode such that the transmitting circuit selects the training command and address signal as an output command and address signal to the memory device according to a command and address clock signal and a chip select clock signal of the timing reference signals; and
the transmitting circuit selects a command and address signal transmitted by a memory access controller to be transmitted as the output command and address signal to the memory device according to the command and address clock signal and the chip select clock signal in the operation mode.

9. The memory access interface device of claim 1, wherein the training data signal and the training data strobe signal are be transmitted as the output data signal and the output data strobe signal to a first-in-first-out (FIFO) circuit having a predetermined depth in the memory device such that the receiving circuit receives the returned data signal and the returned data strobe signal from the first-in-first-out circuit.

10. The memory access interface device of claim 1, wherein the transmitting circuit, the receiving circuit and the signal training circuit operates according to a command clock signal generated by the clock generation circuit.

11. A memory system comprising:
a memory access controller;
a memory device; and
a memory access interface device coupled to the memory access controller, the memory access interface device comprising:
a clock generation circuit; and
a transmitting circuit;
a receiving circuit; and
a signal training circuit configured for executing a training process in a training mode, wherein the training process comprises:
for one of a plurality of loops of the training process in the training mode, generating a training data signal and a training data strobe signal such that the transmitting circuit selects the training data signal and the training data strobe signal to be transmitted as an output data signal and an output data strobe signal to the memory device according to a plurality of timing reference signals generated according to the clock generation circuit each having a phase;
receiving a read data signal from the receiving circuit, wherein the receiving circuit receives a returned data signal and a returned data strobe signal generated by the memory device to generate the read data signal accordingly;
comparing a content of the training data signal and the read data signal to generate a comparison result indicating whether the read data signal matches the content of the training data signal;
storing the comparison result; and
controlling the clock generation circuit to modify the phase of one of the timing reference signals, further modifying the timing of one of the training data signal and the training data strobe signal, to be one of a plurality of under-test phases to execute a new loop of the loops of the training process.

12. A memory access interface device operation method, comprising:
for one of a plurality of loops of a training process in a training mode, generating a training data signal and a training data strobe signal by a signal training circuit of a memory access interface device such that a transmitting circuit of the memory access interface device selects the training data signal and the training data strobe signal to be transmitted as an output data signal and an output data strobe signal to a memory device according to a plurality of timing reference signals generated according to the clock generation circuit each having a phase;
receiving a read data signal from a receiving circuit of the memory access interface device by the signal training circuit, wherein the receiving circuit receives a returned data signal and a returned data strobe signal generated by the memory device to generate the read data signal accordingly;
comparing a content of the training data signal and the read data signal by the signal training circuit to generate a comparison result indicating whether the read data signal matches the content of the training data signal;
storing the comparison result by the signal training circuit; and
controlling the clock generation circuit by the signal training circuit to modify the phase of one of the timing reference signals, further modifying the timing of one of the training data signal and the training data strobe signal, to be one of a plurality of under-test phases to execute a new loop of the loops of the training process.

13. The memory access interface device operation method of claim 12, wherein the timing reference signals comprise a data clock signal corresponding to the training data signal and a data strobe clock signal corresponding to the training data strobe signal, in which the data clock signal and the data strobe clock signal are provided by the clock generation circuit, and the memory access interface device operation method further comprises:
selecting a first one of the data clock signal and the data strobe clock signal as a selected clock signal and a second one of the data clock signal and the data strobe clock signal as a non-selected clock signal by the signal training circuit;
controlling the clock generation circuit to keep the phase of the non-selected clock signal to be a first preferable clock phase by the signal training circuit;
controlling the clock generation circuit to modify the phase of the selected clock signal until all the under-test phases are trained by the signal training circuit;
determining one of the under-test phases of the selected clock signal is valid by the signal training circuit when the corresponding comparison result indicates that the read data signal matches the content of the training data signal; and
determining a second preferable clock phase of the selected clock signal according to the valid under-test phases by the signal training circuit.

14. The memory access interface device operation method of claim 13, further comprising:
setting the memory access interface device to operate in an operation mode by a memory access controller such that the transmitting circuit selects a write data signal and a write enable signal to be transmitted as the output data signal and the output data strobe signal in the operation mode according to the non-selected clock signal having the first preferable phase and the selected clock signal having the second preferable phase.

15. The memory access interface device operation method of claim 14, further comprising:
selecting the training data signal to be transmitted as the output data signal in the training mode and selecting the write data signal as the output data signal in the operation mode by the transmitting circuit by using a data multiplexer coupled to the transmitting circuit; and
selecting the training data strobe signal to be transmitted as the output data strobe signal in the training mode and selecting the write enable signal to be transmitted as the output data strobe signal in the operation mode by the transmitting circuit by using a data strobe multiplexer.

16. The memory access interface device operation method of claim 13, further comprising:
generating the training data signal and the training data strobe signal by a signal generation circuit of the signal training circuit;
comparing the content of the training data signal and the read data signal to generate the comparison result by a comparison circuit of the signal training circuit;
generating a phase control signal to control the clock generation circuit to modify the phase of at least one of a plurality of clock signals to further modify the phase of at least one of the timing reference signals by a phase control circuit of the signal training circuit;
controlling the signal generation circuit and the phase control circuit to execute the loops of the training process and storing the comparison result by a scan circuit of the signal training circuit; and
providing test data for generating the training data signal and the training data strobe signal and for accessing the comparison result to determine the first preferable clock phase of the non-selected clock signal and the second preferable clock phase of the selected clock signal by a control unit of the signal training circuit.

17. The memory access interface device operation method of claim 16, wherein the comparison result comprises a positive edge result and a negative edge result, and further selectively comprises a composite result generated by performing OR logic operation on the positive edge result and the negative edge result.

18. The memory access interface device operation method of claim 12, further comprising:
generating a training command and address signal in the training mode by the signal training circuit such that the transmitting circuit selects the training command and address signal as an output command and address signal to the memory device according to a command and address clock signal and a chip select clock signal of the timing reference signals; and
selecting a command and address signal transmitted by the memory access controller to be transmitted as the output command and address signal to the memory device according to the command and address clock signal and the chip select clock signal by the transmitting circuit in the operation mode.

19. The memory access interface device operation method of claim 12, further comprising:
transmitting the training data signal and the training data strobe signal as the output data signal and the output data strobe signal to a first-in-first-out circuit having a predetermined depth in the memory device such that the receiving circuit receives the returned data signal and the returned data strobe signal from the first-in-first-out circuit.

20. The memory access interface device operation method of claim 12, further comprising:
operating the transmitting circuit, the receiving circuit and the signal training circuit according to a command clock signal generated by the clock generation circuit.
